(19) United States
(12) Patent Application Publication
(10) Pub. No.: US 2014/0233166 A1
(43) Pub. Date: Aug. 21, 2014

(54) FLEXIBLE POWERED CARDS AND DEVICES, AND METHODS OF MANUFACTURING FLEXIBLE POWERED CARDS AND DEVICES

(71) Applicant: Norman E. O'Shea, Seven Fields, PA (US)

(72) Inventor: Norman E. O'Shea, Seven Fields, PA (US)

(21) Appl. No.: 13/770,820

(22) Filed: Feb. 19, 2013

(51) Int. Cl. H05K 1/02

(52) U.S. Cl. CPC H05K 1/0281
USPC 361/679.02; 174/254; 361/749

(57) ABSTRACT

A flexible device, such as a powered card or processor based system, may include a flexible assembly. The flexible assembly may include a die adhered to a flexible substrate (e.g., a PCB) by a flexible adhesive. The die may be stacked with other dies that may be adhered to each other with a flexible adhesive. A conductive pad may be between a flexible substrate and a flexible adhesive. Bond wires may interconnect one or more dies and the flexible substrate via bond pads. In a stacked die configuration, the dies may be thinned using a thinning and/or a polishing process. Such thinned dies may be flexible. The flexible assembly may be flexibly encapsulated.

### BACKGROUND OF THE INVENTION

This invention relates to powered cards and devices and related systems.

### SUMMARY OF THE INVENTION

A device (e.g., a powered card, mobile phone, processor-based system and/or the like) may include a dynamic magnetic communications device, which may take the form of, for example, a magnetic encoder or a magnetic emulator. A magnetic encoder, for example, may be utilized to modify information that is located on a magnetic medium, such that a magnetic stripe reader may then be utilized to read the modified magnetic information from the magnetic medium. A magnetic emulator, for example, may be provided to generate electromagnetic fields that directly communicate data to a read-head of a magnetic stripe reader. A magnetic emulator, for example, may communicate data serially to a read-head of the magnetic stripe reader. A magnetic emulator, for example, may communicate data in parallel to a read-head of the magnetic stripe reader.

All, or substantially all, of the front surface, as well as the rear surface, of a device may be implemented as a display (e.g., bi-stable, non bi-stable, LCD, or electrochromic display). Electrodes of a display may be coupled to one or more touch sensors, such that a display may be sensitive to touch (e.g., using a finger or a pointing device) and may be further sensitive to a location of the touch. The display may be sensitive, for example, to objects that come within a proximity of the display without actually touching the display.

A dynamic magnetic stripe communications device may be implemented on a multiple layer board (e.g., a two-layer flexible printed circuit board). A coil for each track of information that is to be communicated by the dynamic magnetic stripe communications device may then be provided by including wire segments on each layer and interconnecting the wire segments through layer interconnections to create a coil. For example, a dynamic magnetic stripe communications device may include two coils such that two tracks of information may be communicated to two different read-heads included in a read-head housing of a magnetic stripe reader. A dynamic magnetic communications device may include, for example, three coils such that three tracks of information may be communicated to three different read-heads included in a read-head housing of a magnetic stripe reader.

Input and/or output devices may be included on a device, for example, to facilitate data exchange with the device. For example, an integrated circuit (IC) may be included on a device and exposed from the surface of the device. Such a chip (e.g., an EMV chip) may communicate information to a chip reader (e.g., an EMV chip reader). A radio-frequency identification (RFID) antenna or module may be included on a device, for example, to send and/or receive information between an RFID writer/reader and the RFID included on the device.

One or more detectors may be provided on a device, for example, to sense the presence of an external object, such as a person or device, which in turn, may trigger the initiation of a communication sequence with the external object. The sensed presence of the external object may then be communicated to a processor of the device, which in turn may direct the exchange of information between a device, and the external object. Timing aspects of the information exchange between an external object and the various I/O devices provided on a device may also be determined by circuitry (e.g., a processor) provided on a device.

The sensed presence of the external object or device may include the type of object or device that is detected and, therefore, may then determine the type of communication that is to be used with the detected object or device. For example, a detected object may include a determination that the object is a read-head housing of a magnetic stripe reader. Such an identifying detection, for example, may activate a dynamic magnetic stripe communications device so that information may be communicated to the read-head of the magnetic stripe reader. Information may be communicated by a dynamic magnetic stripe communications device, for example, by re-writing magnetic information on a magnetic medium that is able to be read by a magnetic stripe reader or electromagnetically communicating data to the magnetic stripe reader.

One or more read-head detectors, for example, may be provided on a device. The one or more read-head detectors may be provided as, for example, conductive pads that may be arranged along a length of a device having a variety of shapes. A property (e.g., a capacitance magnitude) of one or more of the conductive pads may, for example, change in response to contact with and/or the presence of an object.

A device may, for example, be formed as a laminate structure of two or more layers. A device may, for example, include top and bottom layers of a plastic material (e.g., a polymer). Electronics package circuitry (e.g., one or more printed circuit boards, a dynamic magnetic stripe communications device, a battery, a display, a stacked-die processor, other stacked-die components, wire-bond interconnects, ball grid array interconnects, and buttons) may be sandwiched between top and bottom layers of a laminate structure of a device. A material (e.g., a polyurethane-based or silicon-based substance) may be injected between top and bottom layers and cured (e.g., solidified by an exposure to light, chemicals, or air) to form a hardened device that may include a flexible laminate structure having stacked structures sandwiched between layers of laminate.

A processor, application specific integrated circuit (ASIC), or other circuitry may, for example, be implemented on a semiconductor die. Such a die may, for example, be made to be thinner than its original thickness (e.g., by utilizing a grinding and/or polishing process). Modifying a thickness (e.g., via a grinding or polishing process) of a die may, for example, render a modified die having flexibility attributes. For example, a thinner die may exhibit a minimum bend radius or maximum bend angle without damaging the components of the die. Accordingly, for example, a flexible die may be encapsulated between two flexible sheets of lamination to form a flexible device, which may be flexed to a minimum bend radius without damaging the die.

A component of a flexible device (e.g., a thinned die) may be flexibly adhered to a flexible substrate (e.g., a flexible printed circuit board) with a flexible adhesive. The flexible adhesive may be non-anaerobic and low ionic. The use of a flexible adhesive may decrease a minimum bend radius or maximum bend angle of a flexible device (e.g., a flexible processor based device) by reducing the transfer of force between the flexible substrate and the die. For example, force transferred from a flexible substrate to a die may be due to device bending, material differences and/or imperfections (e.g., wrinkles) in thin flexible substrates, for example, polyimide substrates.

An operation of a flexible device may be altered when the device is flexed. For example, bending a device while the device is in operation may cause the device to function differently (e.g., an oscillator on the device may oscillate at a slightly different frequency as compared to operation when the device is not being flexed). A processor on the device (e.g., a software routine executing on the processor), or an application specific integrated circuit, may detect device flexure and may alert a user as to a degree of the flexure and/or change the operation of flexed devices. For example, a user may be alerted to a degree of flexure by a light source. The light source may indicate when the flexible device exceeds various bend angles (e.g., yellow light for potential damage, red light for likely damage). As another example, the operation of flexed devices may be changed by, for example, changing an amount of current passing through a component based on a degree of flexure to compensate for flexure induced changes of operation.

Flexure may be detected by a detector, for example, a piezoelectric device, a MEMS (e.g., a MEMS capacitor that changes capacitance during flexure), and/or the like. According to some example embodiments, a difference in operation between components (e.g., flexible and non-flexible components) may be used to detect that a device is being flexed.

Components may be stacked. For example, components (e.g., stacked die) may be arranged on a flexible substrate (e.g., a PCB) from bottom to top in order of decreasing diameters. A bottom component may exhibit a larger diameter than a component that is stacked on top of the bottom component. Interconnections (e.g., wire bonds) may be extended from the top component to the bottom component, from the bottom component to the underlying PCB and/or from the top component to the underlying PCB. According to some example embodiments, chip-to-chip interconnections (e.g., flip-chip ball grid arrays) may be used to interconnect the stacked components and/or the underlying PCB.

Stacked components may be flexibly adhered to each other with a flexible, low-ionic, non-anaerobic adhesive. The use of a flexible adhesive may decrease a minimum bend radius or maximum bend angle of a flexible device by reducing the transfer of force between the stacked components, and between the stacked components and a flexible substrate.

### BRIEF DESCRIPTION OF THE DRAWINGS

The principles and advantages of the present invention can be more clearly understood from the following detailed description considered in conjunction with the following drawings, in which the same reference numerals denote the same structural elements throughout, and in which:

FIG. 1 is an illustration of a card constructed in accordance with the principles of the present invention;

FIG. 2 is an illustration of a flexible assembly constructed in accordance with the principles of the present invention;

FIG. 3 is an illustration of a device constructed in accordance with the principles of the present invention;

FIG. 4 is an illustration of a flexible assembly constructed in accordance with the principles of the present invention;

FIG. 5 is an illustration of a flexible assembly constructed in accordance with the principles of the present invention; and

FIG. 6 illustrates process flow charts constructed in accordance with the principles of the present invention.

### DETAILED DESCRIPTION OF THE INVENTION

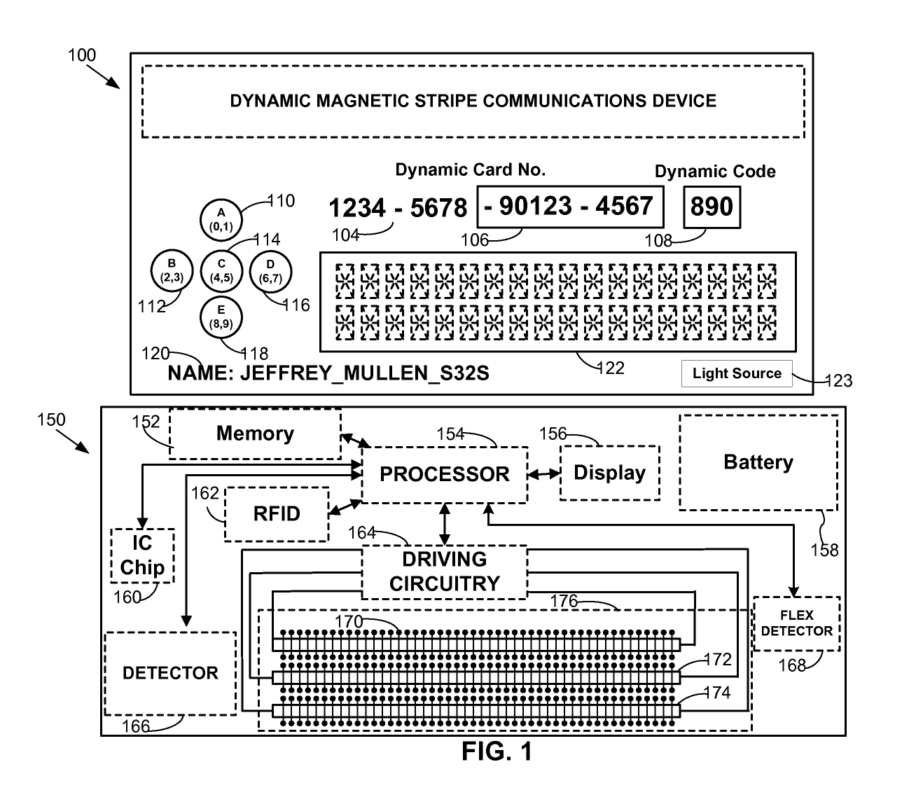

FIG. 1 shows card 100. Referring to FIG. 1, a card 100 may include, for example, a dynamic number that may be entirely, or partially, displayed using a display (e.g., display 106). A dynamic number may include a permanent portion such as, for example, permanent portion 104 and a dynamic portion such as, for example, a number displayed by display 106. Card 100 may include a dynamic number having permanent portion 104 and permanent portion 104 may be incorporated on card 100 so as to be visible to an observer of card 100. For example, labeling techniques, such as printing, embossing, laser etching, etc., may be utilized to visibly implement permanent portion 104.

Card 100 may include a second dynamic number that may be entirely, or partially, displayed via a second display (e.g., display 108). Display 108 may be utilized, for example, to display a dynamic code such as a dynamic security code. Card 100 may also include third display 122 that may be used to display, for example, graphical information, such as logos and barcodes. Third display 122 may also be utilized to display multiple rows and/or columns of textual and/or graphical information.

Persons skilled in the art will appreciate that any one or more of displays 106, 108, and/or 122 may be implemented as a bi-stable display. For example, information provided on displays 106, 108, and/or 122 may be stable in at least two different states (e.g., a powered-on state and a powered-off state). Any one or more of displays 106, 108, and/or 122 may be implemented as a non-bi-stable display. For example, the display is stable in response to operational power that is applied to the non-bi-stable display. Other display types, such as LCD or electrochromic, may be provided as well.

Other permanent information, such as permanent information 120, may be included within card 100, which may include user specific information, such as the cardholder's name or username. Permanent information 120 may, for example, include information that is specific to card 100 (e.g., a card issue date and/or a card expiration date). Information 120 may represent, for example, information that includes information that is both specific to the cardholder, as well as information that is specific to card 100.

Card 100 may accept user input data via any one or more data input devices, such as buttons 110-118. Buttons 110-118 may be included to accept data entry through, for example, mechanical distortion, contact, and/or proximity. Buttons 110-118 may be responsive to, for example, induced changes and/or deviations in light intensity, pressure magnitude, or electric and/or magnetic field strength. Such information exchange may then be determined and processed by a processor of card 100 as data input.

Card 100 may be flexible. Card 100 may, for example, contain hardware and/or software (e.g., flex code stored in memory 152) that when executed by a processor of card 100 may detect when card 100 is being flexed. Flex code may be, for example, processor executable applications and/or may be one or more application specific integrated circuits, that may detect a change in operation of card 100 based on the flexed condition of card 100 and may alter functions of card 100 based on the detected change in operation.

According to at least one example embodiment, a processor of card 100 may receive a signal from a distortion detection element indicating an amount of flexure of card 100. A distortion detection element may be, for example, a microelectricalmechanical system (MEMS), such as a MEMS capacitor. A degree of flexure may be determined according to a signal from the MEMS (e.g., a signal representing a capacitance of the MEMS capacitor). Light Source 123 may provide an indication to a user of the level of flexure of card 100 based on the MEMS signal. For example, light source 123 may be a multicolored light emitting diode (LED) emitting light during flexure of card 100. A color of light source 123 may indicate whether a degree of flexure may result in damage to card 100 (e.g., green for acceptable flexure, yellow for borderline flexure and red for potentially damaging flexure).

FIG. 1 shows architecture 150, which may include one or more processors (e.g., processor 154 which may be a plurality of stacked processors). Processor 154 may be configured to utilize external memory 152, internal memory of processor 154, or a combination of external memory 152 and internal memory for dynamically storing information, such as executable machine language (e.g., flex code), related dynamic machine data, and user input data values. Processor 154 may, for example, execute code contained within memory 152 to detect when a card (e.g., card 100 of FIG. 1) is being flexed. The executed code may, for example, change the operation of a card (e.g., card 100 of FIG. 1) based on the detected change in operation and/or indicate a flexure state to a user (e.g., light source 123 of FIG. 1).

Processor 154 may be a single die, or a combination of two or more die stacked on top of one another. A die may be a thin die attached to a thin and flexible substrate and/or to another die. For example, stacked dies may be flexibly adhered to a mechanical carrier (e.g., a flexible printed circuit board (PCB)), and to each other, using flexible, non-anaerobic, low ionic adhesive. A low ionic adhesive may be an adhesive that includes relatively little (e.g., less than about 20 ppm) or no ionic species that may affect device operation (e.g., migratory species in semiconductor devices) and/or that acts as a barrier to such ionic species.

In the case of a stacked arrangement, a bottom die may exhibit a larger diameter than a die stacked on top of the bottom die. Accordingly, for example, interconnections (e.g., wire bonds) may be placed from one die to another die and/or from each die to the underlying PCB. According to some example embodiments, processor 154 may be a flip-chip combination, where die-to-die and/or die-to-PCB connections may be established using through-die connections and associated interconnections (e.g., a ball grid array (BGA)) with a flexible adhesive between bumps. In so doing, for example, each of the stacked die may exhibit the same or different diameters.

A flexible adhesive may mechanically connect surfaces, or mechanically and electrically connect surfaces, as desired. For example, a conductive, flexible adhesive may electrically connect a die to a conductive pad of a flexible substrate for bulk or body biasing of the die. As another example, an insulating, flexible adhesive may electrically isolate components of a die-to-substrate interface (e.g., BGA isolation).

One or more of the components shown in architecture 150 may be configured to transmit information to processor 154 and/or may be configured to receive information communicated by processor 154. For example, one or more displays 156 may be coupled to receive data from processor 154. The data received from processor 154 may include, for example, at least a portion of dynamic numbers and/or dynamic codes.

One or more displays 156 may be, for example, touch sensitive, signal sensitive and/or proximity sensitive. For example, objects such as fingers, pointing devices, and the like may be brought into contact with displays 156, or in proximity to displays 156. Objects such as light and/or sound emitting device may be aimed at displays 156. Detection of signals, object proximity or object contact with displays 156 may be effective to perform any type of function (e.g., communicate data to processor 154). Displays 156 may have multiple locations that are able to be determined as being touched, or determined as being in proximity to an object. As one non-limiting example, display 156 may be a thin film transistor (TFT) array (e.g., semiconductor oxide TFT array) configured to receive and emit light.

Input and/or output devices may be implemented on architecture 150. For example, integrated circuit (IC) chip 160 (e.g., an EMV chip) may be included within architecture 150, that may communicate information to a chip reader (e.g., an EMV chip reader). Radio frequency identification (RFID) module 162 may be included within architecture 150 to enable the exchange of information with an RFID reader/writer.

Other input and/or output devices may be included within architecture 150, for example, to provide any number of input and/or output capabilities. For example, input and/or output devices may include an audio and/or light device operable to receive and/or communicate audible and/or light-based information. Input and/or output devices may include a device that exchanges analog and/or digital data using a visible data carrier. Input and/or output devices may include a device, for example, that is sensitive to a non-visible data carrier, for example, an infrared data carrier or an electromagnetic data carrier.

Persons skilled in the art will appreciate that a card (e.g., card 100 of FIG. 1) may, for example, include components (including other die components) on a mechanical carrier other than processor 154. RFID 162, IC chip 160, memory 153, a charge coupled device (CCD) (not shown), a semiconductor sensor (e.g., a complementary oxide semiconductor (CMOS) sensor) (not shown), a transducer (not shown), an accelerometer (not shown) and/or flex detector 168 may, for example, each be flexibly adhered with a flexible adhesive to a flexible substrate, and/or to another component.

Flex detector 168 may detect flexure of a device (e.g., card 100). For example, flex detector 168 may include a distortion detection element operable to detect an amount of flexure of a device. Flex detector 168 may be, for example, a MEMS detector, piezoelectric element, detection circuitry, and/or the like.

Two or more device components may be stacked and interconnected. For example, two or more die may be flexibly adhered to each other and interconnected via wire-bonding, ball grid array, or other connection types. Accordingly, for example, surface area on the PCB may be conserved by adding components in vertical fashion rather than adding components laterally across the surface area of the PCB.

Persons skilled in the art will further appreciate that a card (e.g., card 100 of FIG. 1) may, for example, be a self-contained device that derives its own operational power from one or more batteries 158. One or more batteries 158 may be included, for example, to provide operational power for a period of time (e.g., approximately 2-4 years). One or more batteries 158 may be included, for example, as rechargeable batteries.

Electromagnetic field generators 170-174 of dynamic magnetic stripe communications device 176 may be included within architecture 150 to communicate information to, for example, a read-head of a magnetic stripe reader via, for example, electromagnetic signals. For example, electromagnetic field generators 170-174 may be included to communicate one or more tracks of electromagnetic data to read-heads of a magnetic stripe reader. Electromagnetic field generators 170-174 may include, for example, a series of electromagnetic elements. Each electromagnetic element may be implemented as a coil encircling one or more materials (e.g., a magnetic material and/or a non-magnetic material). Additional materials may be outside the coil (e.g., a magnetic material and/or a non-magnetic material).

Electrical excitation by processor 154 of one or more coils of one or more electromagnetic elements via, for example, driving circuitry 164 may generate electromagnetic fields from the one or more electromagnetic elements. One or more electromagnetic field generators 170-174 may be utilized to communicate electromagnetic information to, for example, one or more read-heads of a magnetic stripe reader.

Timing aspects of information exchange between architecture 150 and the various I/O devices implemented within architecture 150 may be determined by processor 154. Detector 166 may be utilized, for example, to sense the proximity and/or actual contact, of an external device, which in turn, may trigger the initiation of a communication sequence. The sensed presence and/or touch of the external device may then be communicated to a controller (e.g., processor 154), which in turn may direct the exchange of information between architecture 150 and the external device. The sensed presence and/or touch of the external device may be effective to, for example, determine the type of device or object detected.

For example, the detection may include the detection of a read-head of a magnetic stripe reader. In response, processor 154 may activate one or more electromagnetic field generators 170-174 to initiate a communications sequence with, for example, one or more read-heads of a magnetic stripe reader. The timing relationships associated with communications between one or more electromagnetic field generators 170-174 and one or more read-heads of a magnetic stripe reader may be based on a detection of the magnetic stripe reader.

Persons skilled in the art will appreciate that processor 154 may provide user-specific and/or card-specific information through utilization of any one or more of buttons 110-118, RFID 162, IC chip 160, electromagnetic field generators 170-174, and/or other input and/or output devices.

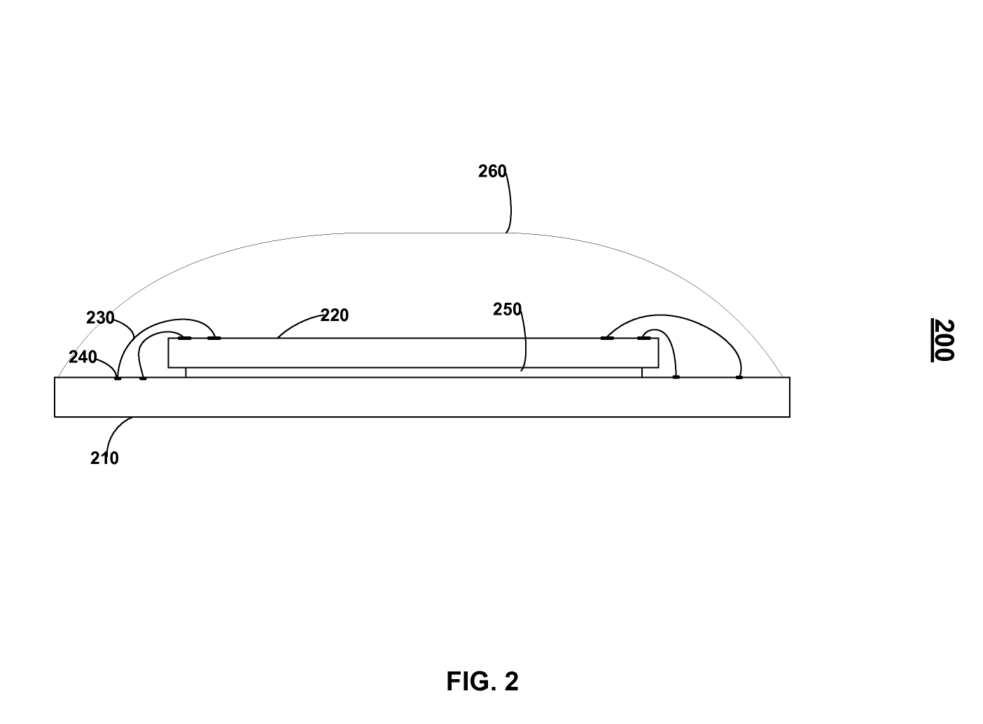

FIG. 2 shows a flexible assembly 200 of a flexible device (e.g., a flexible powered card, mobile phone, computer, and/or the like). Referring to FIG. 2, flexible assembly 200 may, for example, include flexible substrate 210, die component 220, bond wires 230, bond pads 240, flexible adhesive 250 and encapsulant 260.

Die component 220 may include, for example, a thin monocrystalline semiconductor chip in packaged or unpackaged form. Die component 220 may be, for example, a processors, ASIC, mixed-signal device, transistor device, and any other device. Die component 220 may be thinned to increase flexibility and/or decrease thickness (e.g., by a grinding or polishing process). A thinning process may reduce a thickness of die component 220 to a thickness of about 20 microns to 0.00025 inches. A thickness of die component 220 in a stacked configuration may be, for example, about 0.00025 inches to 0.008 inches (e.g., approximately 0.004 inches). A thickness of an unstacked die may be about 0.0018 inches to about 0.0065 inches.

Flexible substrate 210 may be a flexible printed circuit board (PCB) with, for example, a thickness of about 0.001 inches to about 0.003 inches (e.g., without PIC coatings). A material of flexible substrate 210 may include, for example, polyimide, polyester, an organic polymer thermoplastic, laminate material (e.g., FR-4), a liquid crystal polymer, a combination of these materials and/or the like.

Die cracks may be a mode of device failure during flexure. Die cracks may occur due to, for example, flexing of dies adhered to substrates, wrinkled substrates causing uneven force transfer during device flexure and/or a failure to achieve a solid cure/bond between a die and a substrate.

Die component 220 may be adhered to flexible substrate 210 by flexible adhesive 250. Properties of flexible adhesive 250 may include no/low ionic contamination (e.g., less than about 20 ppm for anions or cations, for example, Na+, K+, Cl−, F− and the like), low modulus (e.g., about 0.2 to about 0.05 GPa at 25 degrees centigrade), high stability (e.g., a coefficient of thermal expansion of about 20 to about 100 ppm per degree centigrade) and robust glass transition properties (e.g., a T_{G} of below about 0 degrees centigrade). Flexible adhesive 250 may be non-anaerobic. A non-anaerobic adhesive may be an adhesive with a bonding strength that is generally independent of oxygen contaminants at a bonding surface. Flexible adhesive 250 may be conductive and/or non-conductive, and may be, for example, about 0.0008 to about 0.0012 inches thick.

Flexible adhesive 250 may flexibly adhere die component 220 (or a non-die component) to flexible substrate 210 such that force transfer to die component 220 may be attenuated during bending of a device including flexible assembly 200 (e.g., a powered card and/or flexible mobile phone).

A material of flexible adhesive 250 may change physical state (e.g., change from a liquid substance to a solid substance) when cured by one or more conditions (e.g., air, heat, pressure, light, and/or chemicals) for a period of time. Flexible adhesive 250 may be cured, but may remain flexible, so that flexible substrate 210 may be flexed to exhibit either of a convex or concave shape, while returning to a substantially flat orientation once flexing ceases. Flexure of die component 220 and/or force transfer by flexible substrate 210 to die component 220, may be reduced.

Mechanical and/or electrical interconnections between die component 220 and flexible substrate 210 may, for example, include bond wires 230. Bond wires 230 may be connected to, for example, bond pads 240 on flexible substrate 210, and bond pads 240 on die component 220. Electrical and/or mechanical interconnections between die component 220 and flexible substrate 210 may, for example, include solder balls (not shown). Electrical and/or mechanical interconnections between die component 220 and flexible substrate 210 may, for example, include flip-chip solder balls of a ball grid array.

Bond pads 240 may include a conductive material. For example, bond pads 240 may include aluminum, nickel, gold, copper, silicon, palladium silver, palladium gold, platinum, platinum silver, platinum gold, tin, kovar (e.g., nickel-cobalt ferrous alloy), stainless steel, iron, ceramic, brass, conductive polymer, zinc and/or carbide. The conductive material of a bond pad 210 may be a solder, a flexible printed circuit board trace and/or the like. According to one non-limiting example embodiment, bond pads 240 may be a multi-layer structure (not shown) including a copper (Cu) layer on flexible substrate 210, a nickel (Ni) layer on the Cu layer and a gold (Au) layer on the Ni layer.

Bond pads 240 may be deposited, for example, by thin or thick film deposition (e.g., plating, electroplating, physical vapor deposition (evaporation, sputtering and/or reactive PVD), chemical vapor deposition (CVD), plasma enhanced CVD, low pressure CVD, atmosphere pressure CVD, metal organic CVD, spin coating, conductive ink printing and/or the like. Bond pads 240 may be, for example, magnetic, paramagnetic, solid, perforated, conformal, non-conformal and/or the like. Bond pads 240 may each include a same or different material.

Bond wires 230 may include a conductive material. For example, bond wires 230 may include aluminum, nickel, gold, copper, silicon, palladium silver, palladium gold, platinum, platinum silver, platinum gold, tin, kovar (e.g., nickel-cobalt ferrous alloy), stainless steel, iron, ceramic, brass, conductive polymer, zinc and/or carbide. The conductive material of a bond wire 230 may be coated (e.g., with an insulating material to reduce shorting and/or a conductive material). The material of a bond wire 230 may be, for example, magnetic, paramagnetic, solid, perforated, stranded, braided, and/or the like.

Bond wires 230 may be wire bonded to bond pads 240. Wire bonding may be performed using any wire bonding method. For example, wire bonding may include hand bonding, automated bonding, ball bonding, wedge bonding, stitch bonding, hybrid bonding, a combination of bonding methods and/or the like. Bond wires 230 may each include a same or different material. A material of a bond wire 230 may be the same or different from a material of a bonding pad 240. Each of bond wires 230 may include one or more materials and/or layers.

Through-die vias may, for example, provide electrical connectivity between die component 220, flexible substrate 210 and other components (not shown). For example, electrical signals may be communicated between die component 220, flexible substrate 210 and other components using conductive vias that may extend through die component 220.

Flexible assembly 200 may include encapsulant 260, which may include a layer of material (e.g., a material including one or more polyurethane-based and/or silicon-based substances). A material of encapsulant 260 may be a substance that changes its physical state (e.g., changes from a liquid substance to a solid substance) when cured by one or more conditions (e.g., air, heat, pressure, light, and/or chemicals) for a period of time. Encapsulant 260 may be hardened, but may remain flexible, so that flexible assembly 200 may be flexed to exhibit either of a convex or concave shape, while returning to a substantially flat orientation once flexing ceases.

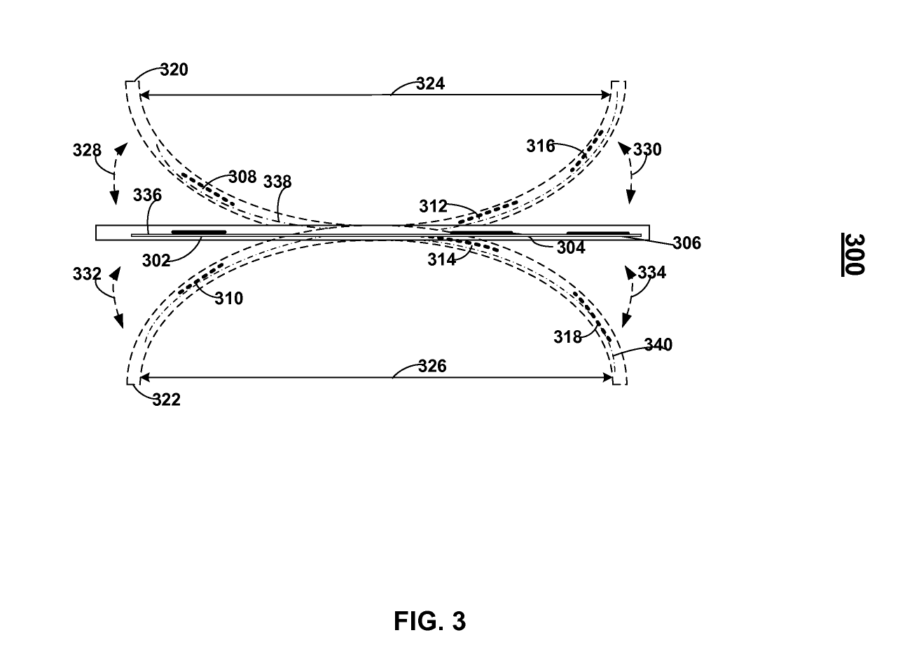

FIG. 3 shows device 300. Referring to FIG. 3, device 300 may, for example, be a laminated assembly including flexible substrate 336, top and bottom layers of a material (e.g., polymer top and bottom layers), and components 302, 304 and 306.

Components 302-306 may be dies (e.g., stacked or non-stacked dies) and/or other components (e.g., a photosensitive device, a sensor, a transducer and/or an accelerometer). Components 302-306 may be flexibly adhered to flexible substrate 336 and/or encapsulated with a flexible material. The encapsulant and/or adhesive may be cured (e.g., hardened) such that device 300 may be rigid, yet flexible, while attenuating force transfer to components 302-306 during flexure.

Components 302-306 may be thinned components. Thinning of components 302-306 (e.g., via a grinding or polishing process) may increase the flexibility of components 302-306 and may, for example, decrease a bend radius at which damage to a component begins to occur.

When device 300 is flexed, an amount of force exerted on components 302-308 may be less than an amount of force exerted on flexible substrate 336 and/or outer layers of device 300. When device 300 is flexed, an amount of flexure of components 302-308 may be less than an amount of flexure of flexible substrate 336 and/or outer layers of device 300.

One or more detectors (not shown) may be placed within device 300 to detect an amount of flexure of device 300 and generate a signal in response. Based on the signal, a light source may be turned on or off, and/or operation of device 300 may be altered.

Device 300 may be flexed in direction 328 and/or 330 to bend device 300 into a concave orientation having minimum bend radius 324. Components 302-306 may assume positions 308-316, respectively, and flexible substrate 336 may assume position 338, as a result of such flexing. Components 302-306 may be flexibly adhered to flexible substrate 336, encapsulated with a flexible material and/or thinned such that flexing may not destroy the operation of components 302-306, and a change in the operation of components 302-306 due to flexure may be reduced.

Device 300 may be flexed in direction 332 and/or 334 to bend device 300 into a convex orientation having minimum bend radius 326. Components 302-306 may assume positions 310-318, respectively, and flexible substrate 336 may assume position 340, as a result of such flexing. Components 302-306 may be flexibly adhered to flexible substrate 336, encapsulated with a flexible material and/or thinned such that flexing may not destroy the operation of components 302-306, and a change in the operation of components 302-306 due to flexure may be reduced.

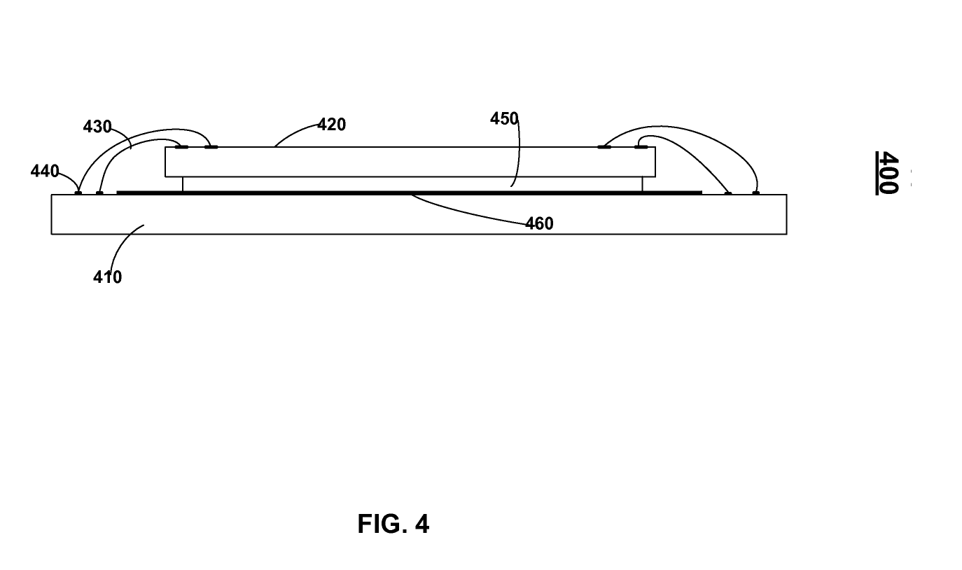

FIG. 4 shows a flexible assembly 400 of a flexible device (e.g., a flexible card, mobile phone, computer, and/or the like). Referring to FIG. 4, flexible assembly 400 may, for example, include a flexible substrate 410, die component 420, bond wires 430, bond pads 440, flexible adhesive 450 and conductive pad 460.

Die component 420 may include, for example, a semiconductor chip in packaged or unpackaged form. Die component 420 may be, for example, a processors, ASIC, mixed-signal device, thin-film transistor device, and any other device. Die component 420 may be thinned, for example, by a grinding or polishing process. A thinning process may reduce a thickness of die component 420 to a thickness of about 20 microns to 0.00025 inches. A thickness of die component 420 in a stacked configuration may be, for example, about 0.00025 inches to 0.008 inches (e.g., approximately 0.004 inches). Die component 420 may be attached to a mechanical carrier.

Flexible substrate 410 may be a flexible printed circuit board (PCB). A material of flexible substrate 410 may include, for example, polyimide, polyester, an organic polymer thermoplastic, laminate material (e.g., FR-4), liquid crystal polymer, a combination of these materials and/or the like. Conductive pad 460 may be on flexible substrate 410, and may include one or more conductive materials. For example, conductive pad 460 may be a multi-layer structure (not shown) including a copper (Cu) layer on flexible substrate 410, a nickel (Ni) layer on the Cu layer and a gold (Au) layer on the Ni layer.

Die component 420 may be adhered to conductive pad 460 by flexible adhesive 450. Properties of flexible adhesive 450 may include no/low ionic contamination, low modulus, high stability and robust glass transition properties.

Flexible adhesive 450 may flexibly adhere die component 420 (or a non-die component) to conductive pad 460 such that force transfer may be attenuated during bending of a device including flexible assembly 400 (e.g., a flexible computing device). Flexible adhesive 450 may be conductive and/or non-conductive. For example, die component 420 may be a body/bulk biased component conductively adhered to conductive pad 460 by a conductive flexible adhesive 450.

A material of flexible adhesive 450 may change physical state (e.g., change from a liquid substance to a solid substance) when cured by one or more conditions (e.g., air, heat, pressure, light, and/or chemicals) for a period of time. Flexible adhesive 450 may be cured, but may remain flexible, so that flexible substrate 410 may be flexed to exhibit either of a convex or concave shape, while returning to a substantially flat orientation once flexing ceases. Flexure of die component 420 and/or force transfer by flexible substrate 410 to die component 420, may be reduced.

Mechanical and/or electrical interconnections between die component 420 and flexible substrate 410 may, for example, include bond wires 430. Bond wires 430 may be connected to, for example, bond pads 440 on flexible substrate 410 and die component 420. Electrical and/or mechanical interconnections between die component 420 and flexible substrate 410 may, for example, include solder balls (not shown). Electrical and/or mechanical interconnections between die component 420 and flexible substrate 410 may, for example, include flip-chip solder balls of a ball grid array.

Through-die vias may, for example, provide electrical connectivity between die component 420, flexible substrate 410 and other components (not shown). For example, electrical signals may be communicated between die component 420, flexible substrate 410 and other components using conductive vias that may extend through die component 420, and may be electrically interconnected via solder balls of a ball grid array. Flexible assembly 400 may include an encapsulant (not shown).

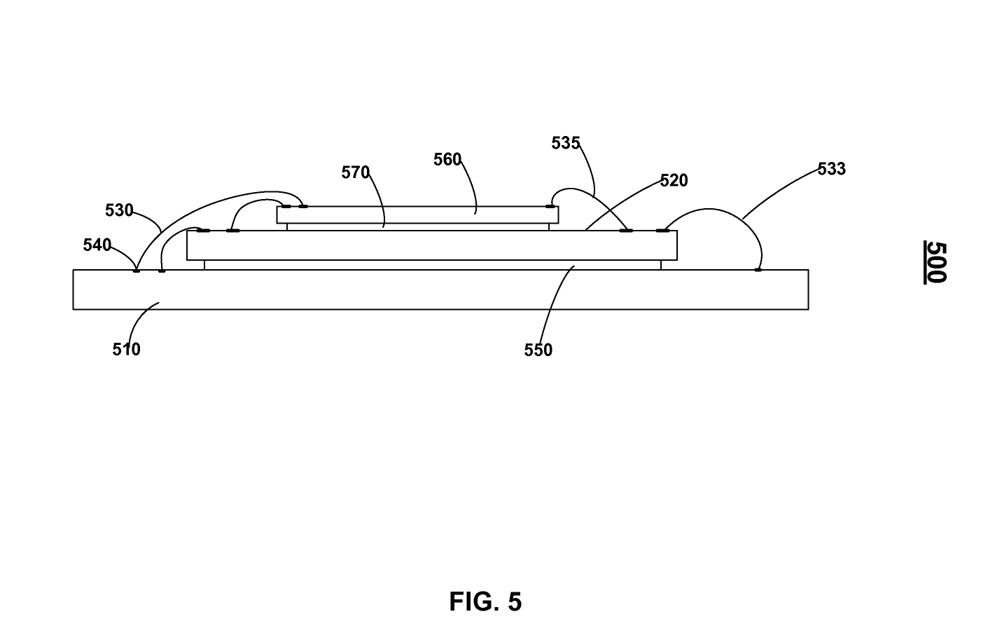

FIG. 5 shows a flexible assembly 500 of a flexible device (e.g., a flexible processing device). Referring to FIG. 5, flexible assembly 500 may, for example, include a flexible substrate 510, stacked components 520 and 560 (e.g., stacked dies), bond wires 530, 533 and 535, bond pads 540, and flexible adhesives 550 and 570.

Flexible assembly 500 may include stacked components 520 and 560 (e.g., stacked dies). Stacked components 520 and 560 may, for example, include one or more processors, ASICs, mixed-signal devices, transistor devices, light sensing devices, wafer sensors, transducers, accelerometers and the like. Stacked components 520 and 560 may, for example, be thinned (e.g., via a grinding or polishing process). Such a thinning process may reduce a thickness of stacked components 520 and 560 to a thickness of about 20 microns to 0.010 inches. A thickness of a component (e.g., a die) may be thinned to about 0.00025 inches to 0.008 inches (e.g., approximately 0.004 inches).

Flexible substrate 510 may be, for example, a flexible printed circuit board (PCB). A material of flexible substrate 510 may include, for example, polyimide, polyester, an organic polymer thermoplastic, laminate materials (e.g., FR-4), liquid crystal polymer, a combination of these materials and/or the like.

Stacked component 520 may or may not be a flexible component, and may be adhered to flexible substrate 510 by flexible adhesive 550. Flexible adhesive 550 may be a flexible, non-anaerobic, low ionic, flexible adhesive. Properties of flexible adhesive 550 may include no/low ionic contamination, low modulus, high stability and robust glass transition properties. Stacked component 560 may or may not be a flexible component, and may be adhered to stacked component 520 by flexible adhesive 570. Flexible adhesive 570 may be the same adhesive as, or a different adhesive from, flexible adhesive 550, and may be a flexible, non-anaerobic, low ionic, flexible adhesive.

Mechanical and/or electrical interconnections between stacked components 520 and 560, and flexible substrate 510 may, for example, include bond wires 530 and 533. Mechanical and/or electrical interconnections between stacked component 520 and stacked component 560 may, for example, include bond wires 535.

Stacked component 560 may be of a smaller diameter as compared to stacked component 520. Bond wire connections between stacked components 520 and 560, between stacked component 520 and flexible substrate 510, and between component 560 and flexible substrate 510 may be facilitated. A plan view (not shown) of component 520, component 560, and flexible substrate 510 may, for example, illustrate that bond pads 540 associated with bond wires 530, 533 and 535 may be staggered so as to substantially reduce a possibility of shorting bond wires to interconnect pads not associated with such bond wires.

Electrical and/or mechanical interconnections between stacked component 520, stacked component 560 and flexible substrate 510 may, for example, include solder balls (not shown), conductive pads (not shown) and/or the like. Accordingly, for example, stacked components 520 and 560 may be of the same, or different, diameters. Persons of ordinary skill in the art in possession of example embodiments will appreciate that although FIG. 5 shows two stacked components, example embodiments are not so limited. Any number of components may be stacked and flexibly adhered.

Through-component vias (e.g., through-die vias) may, for example, provide electrical connectivity between any one or more of stacked components 520 and 560, and flexible substrate 510. For example, electrical signals may be communicated between stacked components 520 and 560, and between any one or more of stacked components 520 and 560, and flexible substrate 510, using conductive vias that may extend through components 520 and 560.

Flexible assembly 500 may include a flexible encapsulant (not shown). Accordingly, for example, flexible assembly 500 may be cured, but may remain flexible, so that a flexible device including flexible assembly 500 may be flexed to exhibit either a convex or concave shape, while returning to a substantially flat orientation once flexing ceases, and reducing and/or eliminating damage to components.

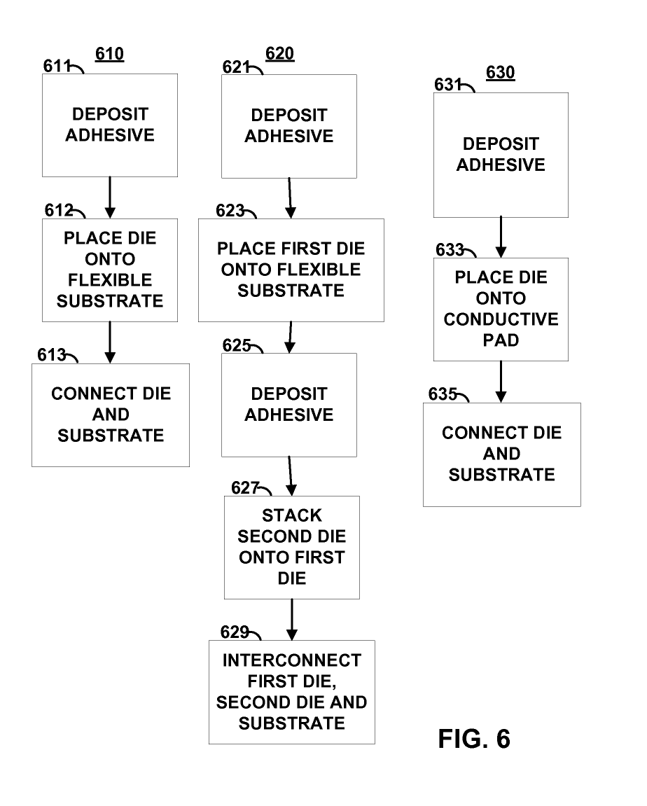

FIG. 6 shows a flow diagram of process sequences. Referring to FIG. 6, step 611 of sequence 610 may include, for example, depositing a flexible, non-anaerobic, low ionic adhesive on a flexible substrate. For example, the material of the flexible adhesive may be deposited as a glob top material on the flexible substrate and/or by selectively depositing the flexible adhesive on the flexible substrate. According to some example embodiments, the flexible adhesive may be deposited onto a die and not the flexible substrate, or onto the die and the flexible substrate.

A die may be placed onto the flexible substrate (e.g., using pick and place) as in step 612. The flexible adhesive between the flexible substrate and the die may not extend beyond the edges of the die after placement. The die may be connected to the flexible substrate via bond pads and wires, and/or solder bumps as in step 613.

Step 621 of sequence 620 may, for example, include depositing a first flexible, non-anaerobic, low ionic adhesive onto a flexible substrate. For example, the material of the first flexible adhesive may be deposited as a glob top material on the flexible substrate and/or by selectively depositing the first flexible adhesive onto the flexible substrate. According to some example embodiments, the first flexible adhesive may be deposited onto a first die and not the flexible substrate, and/or onto the first die and the flexible substrate.

A first die may be placed onto the flexible substrate (e.g., using pick and place) as in step 623. The flexible adhesive between the flexible substrate and the first die may not extend beyond the edges of the die after placement.

A second flexible, non-anaerobic, low ionic adhesive may be deposited onto the first die as in step 625. For example, the material of the second flexible adhesive may be deposited as a glob top material onto an opposite side of the first die from the first flexible adhesive and/or by selectively depositing the second flexible adhesive onto the opposite side. According to some example embodiments, the second flexible adhesive may be deposited onto a second die and not the first die, and/or onto the first die and the second die.

A second die, of a smaller width than a width of the first die, may be placed onto the first die (e.g., using pick and place), within the footprint of the first die, as in step 627. The flexible adhesive between the first die and the second die may not extend beyond the edges of the second die after placement. The first die, second die and flexible substrate may be interconnected via bond pads and wires, and/or solder bumps as in step 629.

According to some example embodiments, stacked dies may be of reduced thickness (e.g., by utilizing a grinding and/or polishing process) to accommodate stacking. For example, a die containing a processor may be placed onto the flexible substrate and another die containing an ASIC may be stacked on top of the die containing the processor. Yet another die (e.g., a die containing mixed-mode electronics or other circuitry) may be stacked onto the die containing the ASIC to yield a three-die stack. Accordingly, for example, by stacking die, surface area of the PCB may be conserved. Such a stacked-die arrangement may be used to produce devices, such as a powered card, a telephonic device (e.g., a cell phone), an electronic tablet, a watch, or any other device. Such a stacked-die arrangement may be encapsulated between two layers of laminate material (e.g., polymer material), injected with an encapsulant, and hardened to produce a rigid, yet flexible device.

Each of the stacked die may be interconnected to each other and/or one or more of the stacked die may be interconnected to signal traces on the flexible substrate. By way of example, such interconnections may be implemented via wire bonds, whereby wires may be attached to interconnect pads of each die. Such wire bonding may be facilitated by placing larger diameter die at the bottom of the stack while placing smaller diameter die in order of decreasing diameter on top of the larger diameter die. In addition, interconnect pads may be staggered (e.g., no interconnect pads of any die or substrate may be directly adjacent to one another in a plan view) to reduce a possibility that wire bonds may make electrical contact with interconnect pads not intended for that wire bond. According to at least one example embodiment, for example, each stacked die may be substantially the same diameter and may be interconnected to each other and the PCB using through-die vias and ball grid array interconnections.

Step 631 of sequence 630 may, for example, include depositing a flexible, non-anaerobic, low ionic adhesive onto a conductive pad of a flexible substrate. For example, the material of the flexible adhesive may be deposited as a glob top material on the conductive pad and/or by selectively depositing the flexible adhesive on the conductive pad. According to some example embodiments, the flexible adhesive may be deposited onto a die and not the conductive pad, and/or onto the die and the conductive pad.

A die may be placed onto the conductive pad of the flexible substrate (e.g., using pick and place) as in step 633. The flexible adhesive between the conductive pad and the die may not extend beyond the edges of the die after placement. The die may be connected to the flexible substrate away from the conductive pad via bond pads and wires, and/or solder bumps as in step 635.

Persons skilled in the art will appreciate that the present invention is not limited to only the example embodiments described. Instead, the present invention more generally involves dynamic information and the exchange thereof. Features described with respect to one example embodiment may be utilized in a different example embodiment. Persons skilled in the art will also appreciate that the apparatus of the present invention may be implemented in other ways than those described herein. All such modifications are within the scope of the present invention, which is limited only by the claims that follow.

What is claimed is:

1. A device, comprising:
a flexible substrate;
a first component on the flexible substrate; and
a first flexible adhesive between the flexible substrate and the component.

2. The device of claim 1, wherein the flexible adhesive is a non-anaerobic, low ionic adhesive.

3. The device of claim 1, further comprising a conductive pad between the flexible substrate and the flexible adhesive.

4. The device of claim 1, further comprising:
a second component on the first component; and
a second flexible adhesive between the first component and the second component.

5. The device of claim 1, further comprising:
at least one bond wire; and
a plurality of bond pads connecting the bond wire to the flexible substrate and the first component.

6. The device of claim 1, further comprising:
a second component on the first component;
a second flexible adhesive between the first component and the second component;
a plurality of bond wires; and
a plurality of bond pads connecting the bond wires to the flexible substrate, the first component and the second component.

7. The device of claim 1, further comprising:
a conductive pad between the flexible substrate and the flexible adhesive,
wherein the flexible adhesive is conductive.

8. The device of claim 1, wherein the first component is a single crystal die.

9. The device of claim 1, wherein the first component is a processor.

10. The device of claim 1, further comprising:
a second component on the first component; and
a second flexible adhesive between the first component and the second component, the second flexible adhesive being different from the first flexible adhesive.
